(19) United States
(12) Patent Application Publication
(10) Pub. No.: US 2023/0105040 A1
(43) Pub. Date: Apr. 6, 2023

(54) CHARGE TRANSFER METHOD AND APPARATUS FOR ELECTROCHEMICAL IMPEDANCE SPECTROSCOPY

(71) Applicant: Safion GmbH, Aachen (DE)

(72) Inventors: Arne Hendrik WIENHAUSEN, Aachen (DE); Hendrik ZAPPEN, Kall (DE)

(73) Assignee: Safion GmbH, Aachen (DE)

(21) Appl. No.: 17/802,662

(22) PCT Filed: Feb. 19, 2021
(86) PCT No.: PCT/EP2021/054236

§ 371 Date: Aug. 26, 2022

(30) Foreign Application Priority Data
Mar. 3, 2020 (EP) 20160638.1

(51) Int. Cl. G01R 31/389; H02J 7/00; G01R 31/396

(52) U.S. Cl. CPC G01R 31/389; H02J 7/0014; G01R 31/396; H02J 2207/20

(57) ABSTRACT

Subjecting batteries with a plurality of cells to a balancing is known. Active balancing is carried out between adjacent cells or cell groups by means of a bus across uninvolved cells. Using this charge transfer for electrochemical impedance spectroscopy is known. The problem is to provide a system and method with which EIS measurements can be carried out on a battery using significantly less equipment outlay, with as little energy loss as possible, on batteries with high capacity and also on those with low excitation frequencies. The problem is solved in that charge is transferred back and forth between a first number of accumulator cells and a second number of accumulator cells during determination of at least one voltage value. The first and second numbers of accumulator cells are wired in series, and the first and second number is at least two.

Subjecting batteries with a plurality of cells to a balancing is known from the prior art, here both a passive and an active balancing are known. Active balancing is carried out between respectively adjacent cells or cell groups, or by means of a bus across uninvolved cells. Active balancing is associated with a relatively high equipment outlay, since each cell must have a corresponding circuit for transferring charge.

From US 2017 163,160 A1 and U.S. Pat. No. 10,393,818 B2 as well as “A Scalable Active Battery Management System with Embedded Real-Time Electrochemical Impedance Spectroscopy”, Din et al., DOI 10.1109/TPEL.2016.2607519, IEEE Transactions on Power Electronics, using an arrangement for active balancing to transfer charge between two adjacent cells is known, and to use this for electrochemical impedance spectroscopy (EIS).

Using an arrangement for active balancing to transfer charge between one cell and the totality of the cells is known from US 2015/0145520 A1, and to use this for electrochemical impedance spectroscopy (EIS).

US 2019 0288520 A1 discloses the division of a battery into two or more modules, and the usage of one of these modules as a voltage supply for a balancing or a test of another of these modules.

To generate an excitation, it is also known to remove energy from one battery or cell and to temporarily store it in a store exterior to the cell or battery, particularly a store capacitor and/or a store inductor, and then to transfer at least part of it into the cell or battery. This is generally carried out periodically, in order to generate an alternating current in the 5 battery and/or cell in this manner. A store is provided for this purpose that is dimensioned so that it can store the energy quantity of the greatest excitation signal, potentially less or plus any losses occurring during the charge transfer between the accumulator and energy store. This is particularly problematic with large batteries and low frequencies of the excitation signal.

The problem is to provide a system and a method with which EIS measurements, particularly of single cells, can be carried out on a battery using significantly less equipment outlay, and this can be done with as little energy loss as possible, and also on batteries with high capacity, and also with low excitation frequencies.

The problem is solved by a method, a usage, and a device, as described in the following:

A method according to the invention is particularly a method for determining at least one impedance value, particularly a plurality of impedance values, of at least one, particularly of all, accumulator cell(s) of a first quantity of accumulator cells.

The method relates to a first quantity of accumulator cells, wherein the first quantity of accumulator cells is formed by a first number of accumulator cells and a second number of accumulator cells.

According to the invention, at least one voltage value, particularly at least one voltage and/or voltage change of at least one of the accumulator cells of the first and/or second number is determined.

According to the invention, the accumulator cells of the first number are wired in series with the accumulator cells of the second number, wherein the first and the second number is respectively at least two, particularly respectively at least six, and wherein the first number of accumulator cells has at least two, particularly at least six accumulator cells wired in series, and wherein the second number of accumulator cells has at least two, particularly at least six accumulator cells wired in series, characterized in that charge is transferred back and forth, particularly periodically, between the first number of accumulator cells and the second number of accumulator cells during the determination of the at least one voltage value.

The problem is also solved by the usage of a charge offset, particularly periodical, between a first number of accumulator cells and a second number of accumulator cells, wherein the first number of accumulator cells and the second number of accumulator cells form a first quantity of accumulator cells. Preferably the charge transfer occurs during the charging or discharging of the first quantity of the accumulator cells, particularly all thereof.

According to the invention, the accumulator cells of the first number are wired in series with the accumulator cells of the second number, wherein the first and the second number is respectively at least two, particularly at least six, and wherein the first number of accumulator cells has at least two, particularly at least six accumulator cells wired in series, and wherein the second number of accumulator cells has at least two accumulator cells wired in series.

According to the invention, at least one voltage value, particularly at least one voltage and/or voltage change of at least one of the accumulator cells of the first and/or at least one voltage value, particularly at least one voltage and/or voltage change of at least one of the second number is further determined.

This occurs particularly for determining at least one impedance value, particularly a plurality of impedance values of at least one, particularly of all, accumulator cells of the first quantity of accumulator cells.

The problem is also solved by an apparatus, particularly for carrying out at least one impedance measurement, particularly electrochemical impedance spectroscopy, configured particularly for determining at least one impedance value, particularly a plurality of impedance values of at least one accumulator cell of a first quantity of accumulator cells. The apparatus is particularly suitable and/or configured for such an arrangement of accumulator cells of the first quantity wherein the first quantity of accumulator cells is formed by a first number of accumulator cells and a second quantity of accumulator cells, wherein the accumulator cells of the first number are wired in series with the accumulator cells of the second number, and wherein the first and the second number is respectively at least two, particularly at least six, and wherein the first number of accumulator cells has at least two, particularly at least six, accumulator cells wired in series, and wherein the second number of accumulator cells has at least two, particularly at least six, accumulator cells wired in series.

The apparatus is further configured to determine at least one voltage value, particularly at least one voltage and/or voltage change of at least one of the accumulator cells of the first or of the second number, wherein the apparatus is further configured to transfer charge, particularly periodically, back and forth between the first number of accumulator cells and the second number of accumulator cells during the determination of the at least one voltage value.

The problem is also solved by a charging device for an accumulator with a first quantity of accumulator cells, wherein the charging device has an apparatus according to the invention and is particularly configured to determine the at least one impedance value, and/or to carry out a method according to the invention during the charging of the accumulator, particularly of all cells of the first quantity.

The problem is also solved by a battery management system, particularly configured for discharge, particularly for using the energy of the discharge, and/or charging an accumulator having a first quantity of accumulator cells, having an accumulator control with an apparatus according to the invention and/or with a charging device according to the invention, and particularly is configured to determine by means of the battery management system the at least one voltage value during the charging and/or discharging of the accumulator, particularly of all accumulator cells of the first quantity.

The problem is also solved by an accumulator having a first quantity of accumulator cells and at least one battery management system and/or charging device according to the invention, and/or an apparatus according to the invention.

The quantity of cells of the first number and the quantity of cells of the second number are disjunct.

The determination of the at least one voltage value occurs particularly continuously, such that a voltage curve is determined as at least one voltage value. Such a voltage curve is particularly determined separately for a plurality of accumulator cells. This occurs particularly without current, by means of a four-point measurement and/or at the anode and cathode of the respective cell. In addition to or instead of the determination of at least one voltage value of at least one single cell or of a parallel circuit of single cells, the total voltage of the cells of the first and/or second number can also be determined.

The absolute voltage and/or the change of the voltage can be determined as the voltage value. Particularly, the voltage change can be determined at least indirectly during the charge transfer.

The at least one voltage value is particularly determined in that conductors and/or particularly the conductors and/or conductor sections used together for determining the at least one voltage value have an impedance of less than 3% of the impedance of the accumulator cells of the first quantity, particularly at every frequency that is part of the excitation signal or part of the charge transfer, particularly every frequency. It is preferable, however, that no conductor sections be used for both determining the at least one voltage value and for the charge transfer. However, there is nothing to oppose using a common conductor for voltage measurement of a first and of a second, electrically adjacent, cell. For example, detection or balancing conductors or ports of the accumulator can be used for this purpose. For the charge transfer, particularly the positive and the negative terminal of the accumulator and/or the beginning point and the end point of the series circuit are used for the first and second number, as well as an additional conductor that engages between the first and second number in their series circuit.

At least one impedance can be determined from the at least one voltage value and at least one current of the charge transfer. Particularly an impedance spectrum is determined; for this purpose, particularly a plurality of frequency components are used for the charge transfer and a plurality of voltage values is determined for each observed accumulator cell. Instead of or in addition to the determination of individual cell impedances, an impedance or an impedance spectrum of the first and/or of the second number can be determined.

An excitation of the accumulator cells by means of the charge offset can be achieved through the invention, particularly without having to temporarily store energy outside of the first quantity of accumulator cells. This simplifies the design and reduces the energy loss. Additionally through the invention, the total voltage of the first quantity of accumulator cells, and therefore particularly of an accumulator, can be kept constant during the charge offset since, for example, the discharge of the first number is balanced out by the simultaneous charge of the second number.

Accordingly the apparatus, the battery management system, the charging device and/or the accumulator do not have a switching element wired in parallel for each of the cells, such as a transistor or MOSFET, particularly has switching elements wired in series to cells only to the extent that each of these switching elements is wired in parallel to at least two cells wired in series, and/or a number of switching elements wired in parallel to cells that is at maximum half the sum of the first and the second number. The determination of the switching element number occurs particularly by counting all switching elements wired in parallel to cells and/or by counting all switching elements wired in parallel to cells such that all switching elements wired in parallel to one another are counted as one switching element. Particularly, the number of switching elements is two.

Particularly the apparatus, the battery management system, the charging device and/or the accumulator do not have any switching elements wired in parallel to the series of cells of the first and the second number, and/or no transformer coils wired in parallel to the series of cells of the first and the second number, and/or no inductors wired in parallel to the series of cells of the first and second number, and/or no capacitors wired in parallel to the series of cells of the first and the second number.

The method and/or the usage are particularly carried out without use of switching elements wired in parallel to the series of cells of the first and second number, and/or without use of transformer coils wired in parallel to the series of cells of the first and second number, and/or inductors wired in parallel to the series of cells of the first and second number, and/or capacitors wired in parallel to the series of the cells of the first and second number.

In this context, the charge transfer can be selected as in known EIS methods, wherein larger currents and lower frequencies can be easily achieved than is possible in the prior art, and this with low equipment outlay. In principle, a DC/DC converter is sufficient to offset the charge between the first number and the second number. In any case, a voltage converter is not to be provided to each cell pair. Advantageously, the charge transfer is accomplished such that the transfer current with which the charge is offset, and/or the current through the first number of accumulator cells, and/or the current through the second number of accumulator cells has a plurality of frequency and/or a plurality of different phase layers, particularly of sinusoidal signal components.

It is not necessary for the periodic charge transfer to be designed periodically for each of the frequencies used if the method is aborted or modified before achieving the periodicity, i.e. after a half period, for example. Thus, for example, only a half wave can be gone through with a short execution of the method at low frequencies. Preferably, however, the charge transfer is periodic in all frequency components.

Particularly preferably, the charge transfer is effected by means of synchronous rectification, and/or the apparatus has at least one synchronous rectifier.

Particularly, at least predominantly, the duty factor of a switch, particularly of one of or the high-side switch, of the voltage converter between d_{1,min} and d_{1,max} is selected with:

$${d}_{1 , min} = \{ \begin{matrix}\frac{{V}_{Bat -}}{{V}_{Bat +} + {V}_{Bat -}} - 0 , 2 & , for \frac{{V}_{Bat -}}{{V}_{Bat +} + {V}_{Bat -}} > 0.3 \\ 0.1 & , for \frac{{V}_{Bat -}}{{V}_{Bat +} + {V}_{Bat -}} \leq 0.3\end{matrix}$$

$${d}_{1 , max} = \{ \begin{matrix}\frac{{V}_{Bat -}}{{V}_{Bat +} + {V}_{Bat -}} + 0 , 2 & , for \frac{{V}_{Bat -}}{{V}_{Bat +} + {V}_{Bat -}} < 0.7 \\ 0.9 & , for \frac{{V}_{Bat -}}{{V}_{Bat +} + {V}_{Bat -}} \geq 0.7\end{matrix}$$

In this context, V_{Bat+} is the total voltage of the first number of accumulator cells and V_{Bat-} is the total voltage of the second number of accumulator cells, and d_{1,min} and d_{1,max} are the limits of the duty factor of a first switch S1 of the voltage converter (i.e., e.g. of the high-side transistor) or of the corresponding PWM signal (PWM1) for actuating the switch. A second switch of the voltage converter (i.e., e.g. of the low-side transistor) is particularly wired complementarily to the first (with a short delay time in which both switches are off, in order to prevent a short circuit through the half bridge). Therefore, particularly the following applies

d₁+d₂+Delaytime1/T_{PWM}+Delaytime2/T_{PWM}=1

with d₂ as the duty factor of the second switching element, d₁ as the duty factor of the first switching element, and T_{PWM} as the period duration of the PWM signal. Particularly, the delaytime1 and delaytime2 together are equivalent to less than 10% of the switching period.

Particularly filter capacitors and/or filter chokes are used for equalizing the artefacts caused in the voltage converter by the switching operations. Filter capacitors and/or filter chokes should be selected such that at maximum amplitude of the charge transfer current, particularly at the maximum charge transfer current for which the apparatus is designed, the ripple current does not exceed 30%, particularly 20% of the maximum current, and/or the ripple voltage does not exceed 20%, particularly 10% of the total voltage of the first quantity of accumulator cells.

Particularly, the at least one voltage value is a voltage change effected by the charge transfer. Particularly the current, particularly the current effecting the charge transfer through the accumulator cells of the first number, and/or the current through the accumulator cells of the second number, is determined, particularly measured. Particularly, the at least one voltage value and/or at least one determined current is used to determine the at least one impedance value. It is not necessary to determine the impedance particularly with known and/or constant current, rather it can be sufficient to regard as transformed a sequence of voltage values in the frequency range that particularly form a complex voltage indicator, because this is then directly correlated to the impedance and represents an impedance value, so to speak.

Particularly preferably, the accumulator cells of the first number are wired in series, particularly directly following one another, and/or the accumulator cells of the second number are wired in series, particularly directly following one another, and/or the accumulator cells of the first number are wired in series with the accumulator cells of the second number, particularly directly following one another, and/or the accumulator cells of the first quantity are wired in series. However it is conceivable, for example, that the first quantity and/or the second quantity each form a mixed series and parallel circuit. In this manner, a plurality of groups of cells wired in parallel among one another can be wired in series. Generally, no individual cell impedance is determined then, but rather the impedance of the cells wired in parallel of a group.

The accumulator cells of the first quantity of accumulator cells are preferably of a single accumulator, wherein the accumulator particularly has no additional accumulator cells.

Particularly, the first number is 50 to 150%, particularly 80-120%, particularly equal to the second numbers, and/or is the total capacity, particularly actual total capacity or nominal total capacity of the accumulator cells of the first number in the range of 80 to 120% of the total capacity, particularly actual total capacity or nominal total capacity of the accumulator cells of the second number. The method can be executed particularly energy-efficiently thereby.

Particularly preferably, the first and/or second number is respectively in the range of 4 or greater, particularly up to 50, particularly in the range from 4 to 30, and/or the first and/or the additional quantities are respectively in the range from 8 to 100, particularly in the range from 10 to 60.

Particularly, the accumulator cells of the first number and of the second number are disjunct, and/or the accumulator cells of the first quantity and of each of the additional quantities are disjunct.

Particularly preferably, the first quantity comprises, or the first quantity and the at least one additional quantity comprise, all accumulator cells of the accumulator.

Advantageously, the accumulator cells are lithium-ion accumulator cells, for example, lithium-cobalt-oxide accumulator cells, lithium-nickel-manganese-cobalt accumulator cells, lithium-nickel-cobalt-aluminum accumulator cells, lithium-manganese accumulator cells, lithium-iron phosphate accumulator cells, and/or lithium-titanium accumulator cells, particularly as lithium polymer accumulator cells.

Preferably the charge transfer is carried out, particularly in an alternating manner, by
partial discharge of the accumulator cells of the first number and charging of the accumulator cells of the second number, and
partial discharge of the accumulator cells of the second number and charging of the accumulator cells of the first number.

In special embodiments, particularly with connection to a power grid or a power source with unneeded output, particularly the discharged output is used for charging, and particularly preferably, the loss output of the charge transfer is equalized by bringing in external energy, particularly from the power grid or the unneeded output.

Particularly the charge and discharge are carried out by means of at least one DC/DC converter, particularly galvanically coupled or galvanically isolated. Galvanically isolated converters are preferred, however.

Particularly the charge transfer is effected and reversed, particularly periodically, particularly with at least one frequency, particularly in the range between 0.1 and 10 kHz, and/or with at least a frequency of 1 kHz or lower.

Particularly the frequency components of the charge transfer below 1 kHz have a charge transfer total current of at least 0.1 A, particularly with nominal total voltage of the accumulator cells of the first quantity of 12V and less, and/or with a first quantity of fewer than 20 accumulator cells.

In this context, the charge transfer total current is particularly the current that is respectively impressed into the first number and/or the second number of cells. In this regard, it is particularly a crest value and/or peak-to-peak value, and/or the effective value, particularly relative to the period duration of the smallest contained frequency.

Particularly the charge transfer occurs exclusively between the totality of the cells of the first number and the totality of the cells of the second number. The charge transfer then occurs, for example, not within the totality of the cells of the first and not within the totality of the cells of the second number. The charge transfer then also occurs, for example, not between an individual cell and the totality of the cells of the first and/or second number. This increases the effectiveness.

Particularly preferably, the frequency components of the charge transfer below 1 kHz have a charge transfer total current of at least 1 A, preferably at least 2 A, particularly preferably of at least 3 A, particularly at a nominal total voltage of the accumulator cells of the first quantity of more than 12 V, and/or a first quantity of more than 20 accumulator cells.

Particularly the charge transfer and the reversed charge transfer are carried out such that in the time average over multiples of the period of the smallest contained frequency, a net charge offset of less than 1% of the nominal capacity of the first quantity takes place between the first number of accumulator cells and the second number of accumulator cells.

In a particular embodiment, the charge transfer and the reversed charge transfer can be carried out such that a balancing is effected between the accumulator cells of the first number and of the second number, particularly by superimposing a direct current on the charge transfer signal.

Particularly the charge transfer and the reversed charge transfer are carried out such that the total voltage of the first quantity, of the quantities, and/or of the accumulator fluctuates less than 2%, wherein particularly the amplitude of the voltage fluctuation of at least one of the accumulator cells of the first quantity is at least 1 mV.

Advantageously, at least one voltage value of a plurality is measured, particularly each accumulator cell(s) of the first and/or of the second number, respectively, and/or at least one total voltage value of the first number of accumulator cells and/or of the second number of accumulator cells, respectively. Thereby with an excitation signal, a statement can be made about a plurality of cells.

The at least one voltage value or each of the at least one voltage values is particularly a quantity of sequential voltage values and/or a voltage curve, particularly with an interval of individual voltage measurements of less than 100 ms.

The voltage values, particularly the quantity of sequential voltage values are preferably respectively subject to a Fourier transformation at the same measurement points and/or the accumulator cell(s), particularly in order to determine the at least one impedance.

In a possible embodiment, the method can be carried out with at least one additional quantity of accumulator cells, particularly as with the first quantity, particularly simultaneously, wherein all accumulator cells of the first and the additional quantity are wired in series, particularly directly following one another or are wired in parallel.

Advantageously, the accumulator cells of the first quantity and/or the accumulator cells of the first and of the at least one additional quantity are arranged in a shared housing. Advantageously, this housing comprises, particularly only the accumulator cells with their surrounding sleeves, and optionally an apparatus according to the invention, for example a battery management system according to the invention, and/or no additional active components.

Advantageously, the voltage measurement and/or the charge transfer occurs by means of at least one balancing connection and/or at least one sense conductor of the accumulator. In this context, it should be particularly noted that it is advantageous for conductor sections used jointly for voltage measurement and charge transfer to correspond to the stated requirements, particularly to be avoided entirely.

Advantageously, the method is operated such that in the time average, regarded particularly over a time span of integer multiples of the period duration of the smallest contained frequency, a net charge transfer, particularly between the first and the second number, of less than 1% of the nominal capacity of the accumulator occurs, particularly per hour, particularly no net charge transfer occurs between the accumulator cells of the first number and of the second number.

A particular advantage of the method is that the charge transfer and/or the determination of the at least one voltage value can occur during the charging or discharging, particularly for using the energy of the accumulator, especially that of all of its accumulator cells, and particularly occurs without having to accept larger disadvantages.

This enables the use of the invention, particularly continuous use thereof, during normal and particularly uninterrupted use of the first and/or of the additional quantities of the accumulator cells. An autonomous and continuous monitoring during use is possible, since moreover with continuous measurement the loss output can be below 1% of the nominal energy per hour, and also the required electrical output for the control of the charge transfer and of the voltage measurement, and of the processing, can be kept under 30 W.

Particularly advantageously, the charge transfer current and/or the excitation signal has components with different phase layers and/or different frequencies. Advantageously, the energy quantity, particularly that effected by the charge transfer, and/or periodically, and/or through the method, stored in an energy store outside of the accumulator and/or the accumulator cells of the first quantity, and/or of the first quantity and the additional quantities, particularly in a capacitor, can be kept lower than

$$\frac{{\hat{l}}_{f} \cdot ( {U}_{open - circuit} + {\hat{u}}_{f} )}{2 \cdot {f}_{min}}$$

In this context, î_{f} is the maximum amplitude of the excitation signal or of the charge transfer current (measured in Amperes), U_{open-circuit} is the nominal total voltage or total open-circuit voltage of the first quantity of accumulator cells (measured in Volts), and 1 is the maximum amplitude of the sum of the individual voltage response of the accumulator cells of the first quantity and/or of the first quantity and the additional quantities (measured in Volts).

According to the invention, energy is particularly stored temporarily only by the filtering and/or by the voltage converter, this occurs particularly in the time horizon, and/or at maximum over the timespans of the duration between changeovers of the switching elements of the voltage converter, and/or over significantly shorter timespans than the periods of the, particularly of all of the, frequency components of the charge transfer current, particularly between the first and second number of accumulator cells, particularly only over timespan of a maximum of 1/10, particularly of a maximum of 1/50 of the periods of the lowest frequency of the charge transfer current, particularly between the first and second number of accumulator cells, and/or of the excitation signal. Advantageously for this purpose, the filter capacitor and/or filter is charged only up to a medium voltage, particularly the, particularly average total voltage of the first quantity and/or first and/or second number of accumulator cells.

Particularly the at least one filter capacitor and/or filter stores a constant base energy over long periods, particularly over the entire duration of the method, said energy particularly arising in that it is charged at the, particularly average total voltage of the first quantity and/or of the first and/or second number of accumulator cells. The observation of the duration of the temporary store then relates particularly only to the difference relative to this base energy.

Particularly the invention has and/or the method uses, particularly for charge transfer between the first and second number of accumulator cells, per first or first and additional quantity, particularly absolutely, at maximum a group of voltage converters wired in parallel, particularly fewer voltage converters than the number of cells of the accumulator, particularly of the first quantity, particularly of the first number, less one, particularly less two, particularly less ten.

Particularly the apparatus has and/or the method uses no voltage converters wired in series, particularly for charge transfer between the first and second number of accumulator cells.

Particularly for charge transfer, particularly between the first and second number of accumulator cells, the apparatus has and/or the method uses no voltage converters wired in series such that the charge transfer current flows sequentially through more than one voltage converter.

In general, the wattage of the excitation signal or charge transfer current can be expressed particularly as follows:

$${s}_{scaled} ( t ) = {r}_{scale} \cdot {\sum }_{k = 1}^{N} {a}_{k} \cdot sin ( 2 π {f}_{k} t + {ϕ}_{k} )$$

$$where \sum {a}_{k} = 1.$$

Advantageously, r_{scale} is selected such that the following conditions are satisfied for the peak value iₚₑₐₖ of the excitation signal or charge transfer current:
the peak value iₚₑₐₖ of the current excitation or of the charge transfer current is selected such that the maximum voltage response amplitude of an accumulator cell has a value of 20 mV at maximum, and/or
in the event of a plurality of simultaneously excited frequencies, the excitation signal or the charge transfer current has a peak factor or crest factor of 2.6 or less, and/or
the excitation signal or the charge transfer current has an effective output greater than

$${k}^{2} = \frac{{i}_{peak}^{2}}{{i}_{rms}^{2}} = \frac{{i}_{peak}^{2}}{{p}_{rms}} ⇒ {p}_{rms} = \frac{{i}_{peak}^{2}}{{k}^{2}} ⇒ {p}_{rms} \geq \frac{{i}_{peak}^{2}}{{2.6}^{2}}$$

Particularly advantageously, the apparatus, the charging device, and/or the battery management system has a control apparatus configured for carrying out the method according to the invention by means of the apparatus, the charging device, and/or the battery management system.

Particularly advantageously, the apparatus is formed such that it does not have any energy store, particularly capacitors and coils, for temporarily storing energy, particularly from a measurement, that has a total energy storage capacity of more than

$$\frac{{u}_{max} \cdot {i}_{max}}{4 \cdot {f}_{min}}$$

wherein uₘₐₓ is the maximum accumulator voltage or maximum total voltage of the accumulator cells of the first quantity for which the apparatus is configured, and max is the maximum charge transfer current intensity for which the apparatus is configured, and fₘᵢₙ is the minimum charge transfer frequency or the minimum frequency component in the charge transfer current for which the apparatus is configured.

Particularly advantageously, the charging device has a balancer and balancer ports for connecting to balancing connections or sense conductors of the accumulator, and is particularly configured to carry out the determination of the at least one voltage using at least one balancing port, balancing connection, or at least one sense conductor.

Advantageously, the battery management system is particularly configured for discharge, particularly for using the energy of the discharge, and/or charging an accumulator with a first quantity of accumulator cells, wherein the battery management system has an apparatus according to the invention, and is particularly configured to determine the at least one voltage value during the charging and/or discharging of the accumulator by means of the battery management system.

The method is particularly carried out by means of an apparatus, an accumulator, charging device, and/or battery management system according to the invention.

Further advantages and possible embodiments are intended purely as examples in the following purely schematic figures. They show:

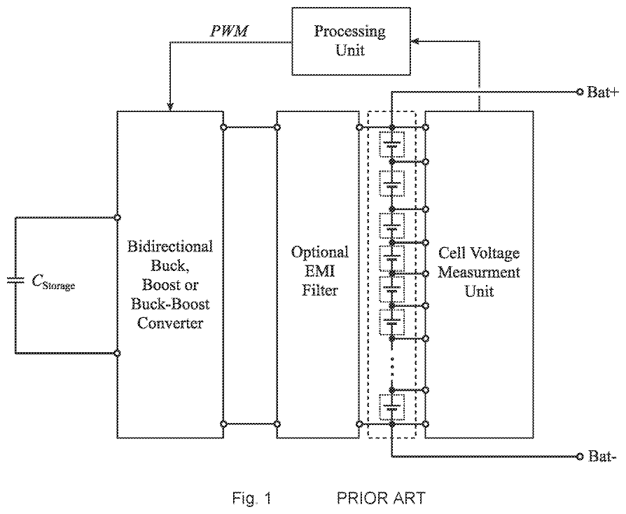

FIG. 1: a depiction of a prior art EIS arrangement

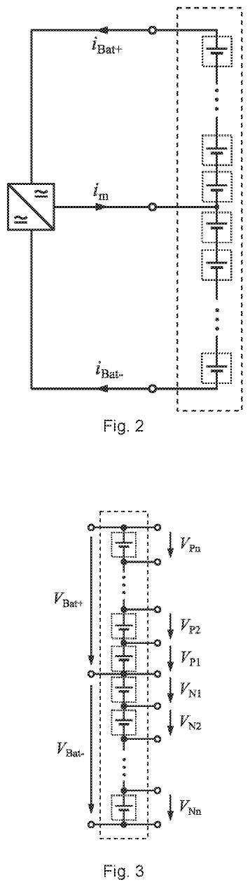

FIG. 2 a simplified schematic depiction of the circuit for generating the charge transfer according to the present invention

FIG. 3 a depiction of various voltages at an accumulator

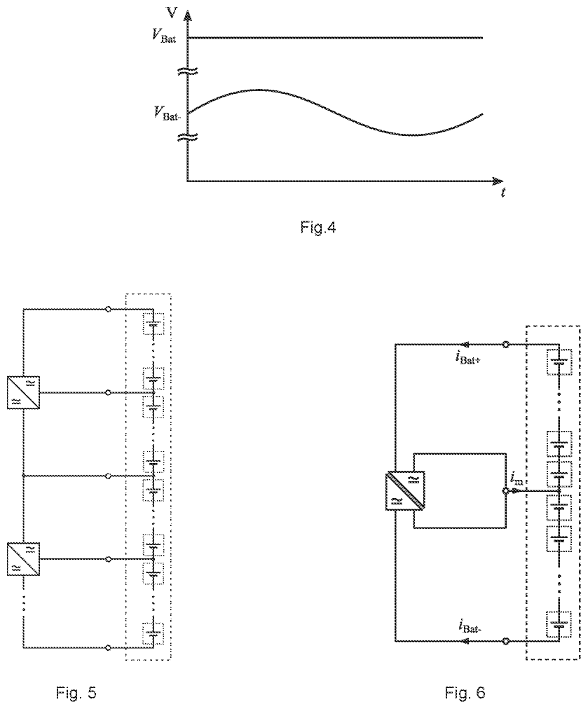

FIG. 4 an idealized voltage curve of two voltage curves during the method according to the invention

FIG. 5 an arrangement with a first and a second quantity

FIG. 6 an arrangement with a galvanically isolated voltage converter

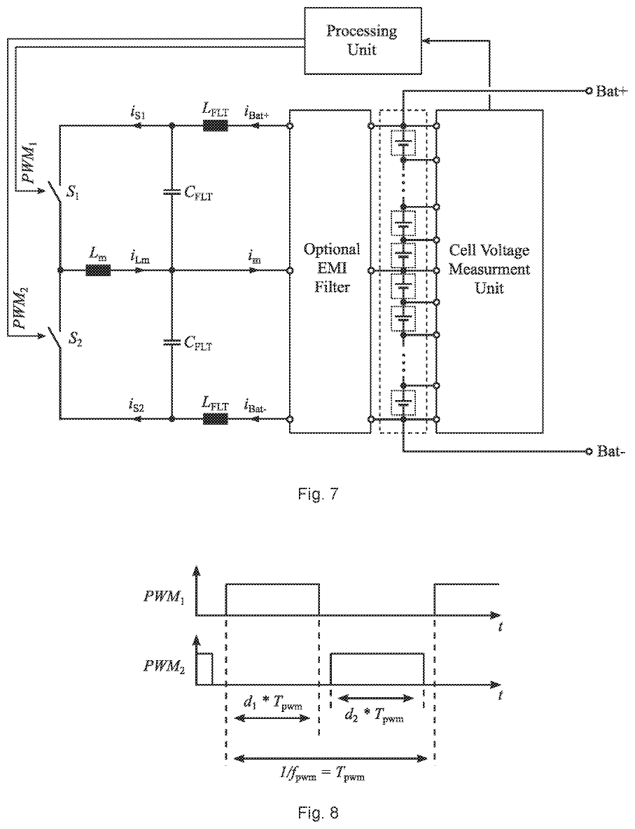

FIG. 7 a detailed depiction of an apparatus according to the invention with an accumulator

FIG. 8 a depiction of the actuation of two circuits of a rectifier from FIG. 7

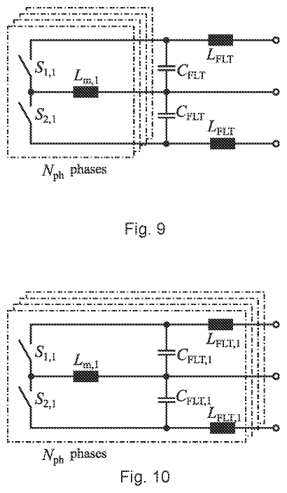

FIG. 9 a depiction of a plurality of voltage converters with a shared filter for generating phase-offset current components

FIG. 10 a depiction of a plurality of voltage converters, respectively with a dedicated filter for generating phase-offset current components

FIG. 1 shows an arrangement of a first quantity of accumulator cells wired in series. Sense conductors that lead to a voltage measuring unit are arranged between each of the accumulator cells, and at the beginning and end of the series circuit. At the end and the beginning of the series circuit, there is a unit for generating the charge transfer via an optional filter, in this case from the entire arrangement of accumulator cells into a store capacitor and back. Furthermore, a unit for controlling the charge transfer is arranged in the upper region.

Referring back to the introductory depiction of the prior art, it is noted here that arrangements are known that carry out a charge offset between neighboring cells with at least one voltage converter per cell pair and do not have a store capacitor.

FIG. 2 shows an arrangement with an accumulator with a first number of accumulator cells and a second number of accumulator cells, all of which are wired in series. Between the first and the second number, a conductor for the charge transfer is arranged, which occurs by means of the voltage converter of the two conductors arranged at the positive and negative terminal of the accumulator. The voltage measurement is not shown here in the interest of clarity. Conversely, three exemplary conceivable locations for a measurement of the charge transfer current are depicted. In principle, in a symmetrical division of the accumulator cells of the first quantity into a first and second number, it would also be sufficient to measure iₘ. However, i_{Bat+} and/or i_{Bat-} can also be determined alternatively and/or together.

FIG. 3 illustrates the voltage measurement not shown in FIG. 2. The accumulator possesses a plurality of connections for the voltage measurement (on the right in the image) and three connections for the charge transfer/left side). Depicted are the individual cell voltages of the individual accumulator cells of the first number V_{P1} to V_{Pn}, and of the second number V_{N1} to V_{Nn}. Therefore the accumulator is suitable for a four-point measurement at each accumulator cell, in that a charge transfer is effected by means of the connections of the left side, and voltage measurements occur by means of the right connections. The total voltage of the first number of accumulator cells V_{Bat+} and of the second number of accumulator cells V_{Bat-} can also be measured.

FIG. 4 shows resulting voltages, omitting the switching artefacts of the voltage converter. In this context, V_{Bat} is the total voltage of the accumulator. It is evident that while V_{Bat-}, of which only a single sinus component is shown here, fluctuates sinusoidally, V_{Bat} remains nearly constant, however.

FIG. 5 shows an arrangement with a first quantity, arranged between the uppermost three horizontal conductors, and a second quantity, arranged between the lowermost three horizontal conductors. A voltage converter is assigned to each quantity. The dots in the accumulator are intended to suggest that a plurality of not shown cells are also arranged in series here. The dots at the lower left are intended to suggest that beyond this, further additional quantities can follow, wherein the lowermost accumulator cell always belongs to the lowest quantity.

FIG. 6 shows an arrangement as in FIG. 2, however with galvanic isolation.

FIG. 7 shows a detailed depiction of an arrangement according to the invention based on the prior art of FIG. 1. A voltage converter with switches S₁ and S₂ depicted in detail is evident, as well as capacitors and inductors. Said voltage converter is connected to three connections of an accumulator by means of an optional, i.e. dispensable, filter, and specifically at the positive terminal, at the negative terminal, and once between the cells wired in series. The switches S1 and S2 are actuated by means of PWM by the switching signals PWM1 and PWM2, which are generated in a control and computing unit. The individual voltage measurement unit for measuring all individual voltages of the accumulator cells is depicted schematically on the right side.

FIG. 8 illustrates the switching signals PWM1 and PWM2 from FIG. 7. The duty durations d₁*T_{pwm} and d₂*T_{pwm} as well as the duty factors d₁ and d₂ of the switches S₁ and S₂ are evident, as are the delay times occurring between the duty durations.

FIG. 9 shows a parallel circuit of a plurality of voltage converters that use a shared filter, via which they are connected to accumulator cells. Such an arrangement can, for example, replace the individual voltage converters and the filter from FIG. 7. Particularly, the switches of the individual voltage converters are actuated such that they, particularly approximately (deviations result particularly from the non-synchronous actuation by the corresponding controllers), generate the same current curve, however phase-offset to one another. Additionally or alternatively, a parallel circuit of voltage converters can also be used, each having its own filter. This is shown in FIG. 10. Additionally or alternatively, a parallel circuit of voltage converters can be used, each of which generates a different current curve, particularly different frequency components. A single voltage converter, insofar as it can be switched quickly enough, can be used to generate different signal components, for example phase-offset and/or with different frequencies.

1. A method for determining at least one impedance value of at least one accumulator cell of a first quantity of accumulator cells, wherein the first quantity of accumulator cells is formed by a first number of accumulator cells and a second number of accumulator cells, wherein at least one voltage value or voltage change, of at least one of the accumulator cells of the first number or of the second number is determined, wherein the accumulator cells of the first number are wired in series with the accumulator cells of the second number, and wherein the first number and the second number respectively is at least two, and wherein the first number of accumulator cells has at least two accumulator cells wired in series, and wherein the second number of accumulator cells has at least two accumulator cells wired in series, wherein charge is transferred back and forth between the first number of accumulator cells and the second number of accumulator cells during the determination of the at least one voltage value.

2. The method according to claim 1, wherein the accumulator cells of the first number are wired in series or wherein the accumulator cells of the second number are wired in series, or wherein the accumulator cells of the first number are wired in series with the accumulator cells of the second number, or wherein the accumulator cells of the first quantity of accumulator cells are wired in series.

3. The method according to claim 1, wherein the charge and discharge is carried out by means of at least one DC/DC converter.

4. The method according to claim 1, wherein the accumulator cells of the first quantity are accumulator cells of a single accumulator.

5. The method according to claim 1, wherein the charge transfer is effected and reversed.

6. The method according to claim 5, wherein the charge transfer and the reversed charge transfer are carried out such that in a time average over multiples of a period of a smallest contained frequency, no net charge offset takes place between the first quantity of accumulator cells and a second quantity of accumulator cells.

7. The method according to claim 4, wherein the charge transfer is carried out such that a total voltage of the first quantity of accumulator cells, of the quantities, or of the single accumulator fluctuates less than 2% or wherein the charge transfer and the reversed charge transfer or the determination of the at least one voltage value occurs during the charging or discharging.

8. The method according to claim 5, wherein a stored energy quantity effected by the charge transfer or periodically or by the method, in an energy store outside of a single accumulator and/or of the accumulator cells of the first quantity and or/or of the first quantity and additional quantities is kept less than
$$\frac{{\hat{l}}_{f} \cdot ( {U}_{open - circuit} + {\hat{u}}_{f} )}{2 \cdot {f}_{min}} ,$$
wherein î_{f} is a maximum amplitude of the excitation signal or of the charge transfer current, U_{open-circuit} is a nominal total voltage or total open-circuit voltage of the first quantity of accumulator cells, and û_{f} is a maximum amplitude of the sum of the individual voltage response of the first quantity of accumulator cells.

9. An apparatus for carrying out at least one impedance measurement, configured for determining at least one impedance value of at least one accumulator cell of a first quantity of accumulator cells, wherein the first quantity of accumulator cells is formed by a first number of accumulator cells and a second number of accumulator cells, wherein the apparatus is configured to determine at least one voltage value of at least one of the accumulator cells of the first number or of the second number, wherein the accumulator cells of the first number are wired in series with the accumulator cells of the second number, and wherein the first number and the second number, respectively, are at least two, and wherein the first number of accumulator cells has at least two accumulator cells wired in series, and wherein the second number of accumulator cells has at least two accumulator cells wired in series, wherein the apparatus is configured to transfer charge back and forth between the first number of accumulator cells and the second number of accumulator cells during the determination of the at least one voltage value.

10. The apparatus according to claim 9, having a control apparatus configured for carrying out a method for determining at least one impedance value of at least one accumulator cell of a first quantity of accumulator cells, wherein the first quantity of accumulator cells is formed by a first number of accumulator cells and a second number of accumulator cells, wherein at least one voltage value or voltage change, of at least one of the accumulator cells of the first number or of the second number is determined, wherein the accumulator cells of the first number are wired in series with the accumulator cells of the second number, and wherein the first number and the second number respectively is at least two, and wherein the first number of accumulator cells has at least two accumulator cells wired in series, and wherein the second number of accumulator cells has at least two accumulator cells wired in series, wherein charge is transferred back and forth between the first number of accumulator cells and the second number of accumulator cells during the determination of the at least one voltage value.

11. The apparatus according to claim 9, wherein the apparatus is configured to temporarily store energy, only for a maximum of 1/10 of the period of the lowest frequency of the charge transfer or excitation signal for which the apparatus is configured, or for a maximum of ten times the greatest closing time of a switching element used for the charge transfer that is provided in the apparatus, in the apparatus or outside of the first quantity of accumulator cells or of an accumulator of a voltage converter, or wherein the apparatus that in sum cannot store more energy than
$$\frac{{u}_{max} \cdot {i}_{max}}{4 \cdot {f}_{min}} [ [ , ] ]$$
wherein uₘₐₓ is a maximum accumulator voltage or maximum total voltage of the accumulator cells of the first quantity for which the apparatus is configured, and iₘₐₓ is a maximum charge transfer current intensity for which the apparatus is configured, and fₘᵢₙ is a minimum charge transfer frequency or a minimum frequency component in the charge transfer current for which the apparatus is configured.

12. A charging device for an accumulator with a first quantity of accumulator cells, wherein the charging device has an apparatus according to claim 9 and is configured to determine the at least one impedance value.

13. A battery management system, having an apparatus according to claim 9.

14. An accumulator having a first quantity of accumulator cells and at least one battery management system according to claim 13.

15. Usage of a charge offset, between a first number of accumulator cells and a second number of accumulator cells, wherein the first number of accumulator cells and the second number of accumulator cells form a first quantity of accumulator cells, wherein the accumulator cells of the first number are wired in series with the accumulator cells of the second number, or wherein the first number and the second number is respectively at least two, and wherein the first number of accumulator cells has at least two accumulator cells wired in series, and wherein the second number of accumulator cells has at least two accumulator cells wired in series, wherein at least one voltage value of at least one of the accumulator cells of the first or of the second number is determined, for determining at least one impedance value.

16. The method according to claim 1, wherein charge is periodically transferred back and forth between the first number of accumulator cells and the second number of accumulator cells during the determination of the at least one voltage value.

17. The method according to claim 1, wherein the single accumulator does not have any additional accumulator cells.

18. The method according to claim 1, wherein the charge transfer is effected and reversed periodically.

19. The method according to claim 1, wherein the charge transfer is effected, with at least one frequency in the range between 0.1 and 10 kHz or with at least one frequency of 1 kHz or less

20. The method according to claim 1, wherein the charge transfer is effected so that frequency components of the charge transfer below 1 kHz have a charge transfer total current of at least 0.1 A.

21. The method according to claim 1, wherein the charge transfer is effected, at a nominal total voltage of the accumulator cells of the first quantity of accumulator cells of 12 V and less.

22. The method according to claim 1, wherein charge transfer current is at least 1 A.

23. The apparatus according to claim 9, wherein the apparatus is configured to periodically transfer charge back and forth between the first number of accumulator cells and the second number of accumulator cells during the determination of the at least one voltage value.

24. The usage according to claim 15, wherein said charge offset is performed periodically.
